(19) United States
(12) Patent Application Publication
(10) Pub. No.: US 2025/0220942 A1
(43) Pub. Date: Jul. 3, 2025

(54) SEMICONDUCTOR DEVICE AND METHODS OF FABRICATION THEREOF

(71) Applicant: TAIWAN SEMICONDUCTOR MANUFACTURING COMPANY, LTD., Hsinchu (TW)

(72) Inventors: Yi-Chen LO, Zhubei (TW); Ding-Kang SHIH, New Taipei (TW); Chia-Yun CHENG, Hsinchu (TW); Yu-Wei LU, Taipei (TW)

(21) Appl. No.: 18/402,178

(22) Filed: Jan. 2, 2024

(51) Int. Cl. H01L 29/66; H01L 21/311; H01L 29/06; H01L 29/423; H01L 29/775; H01L 29/786

(52) U.S. Cl. CPC H10D 30/024; H01L 21/31116; H10D 30/014; H10D 30/43; H10D 30/6735; H10D 30/6757; H10D 62/121

(57) ABSTRACT

A method is provided. The method includes forming a plurality of stacks of semiconductor layers. Each of the stacks includes a plurality of first semiconductor layers and a plurality of second layers alternately stacked with each other. A gate electrode structure is then formed on each of the stacks of semiconductor layers, each of the gate electrode structures including a gate spacer. An epitaxial layer is formed in an opening between each pair of neighboring stacks of semiconductor layers. After formation of the epitaxial layer, oxygen ion beams are applied to the gate spacer with a tilt angle to form oxidized materials on the gate spacers with a tilt angle. The oxidized materials are then removed by diluted HF solution.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, transistors using nanowire channels have been proposed to achieve increased device density, greater carrier mobility and drive current in a device. As device size reduces, there is a continuous need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 are perspective views of various stages of manufacturing a semiconductor device structure, in accordance with some embodiments.

FIGS. 9-21 are cross-sectional side views of various stages of manufacturing the semiconductor device structure taken along cross-section A-A of FIG. 8, in accordance with some embodiments.

FIG. 22 is an enlarged view of a region within a dash-line frame as shown in FIG. 21.

FIG. 23 is a flowchart of a method for fabricating the semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs). While the embodiments of this disclosure are discussed with respect to GAA devices, implementations of some aspects of the present disclosure may be used in other processes and/or in other devices. A person having ordinary skill in the art will readily understand other modifications that may be made are contemplated within the scope of this disclosure.

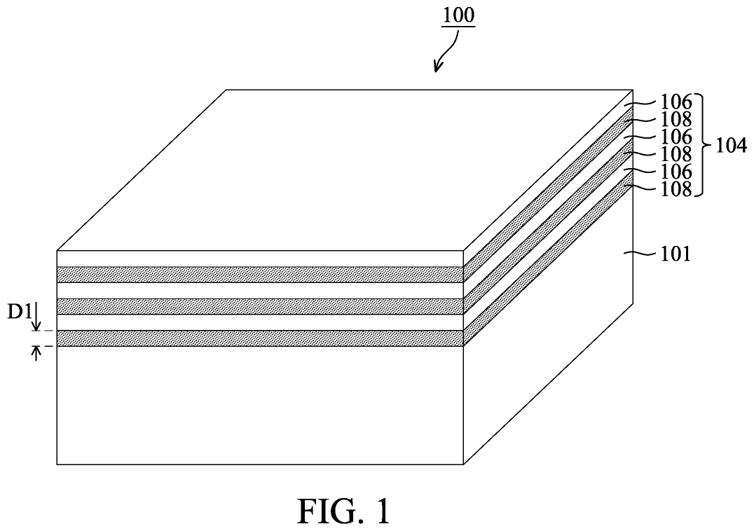

FIGS. 1-21 show exemplary processes for manufacturing a semiconductor device structure 100 according to embodiments of the present disclosure. It is understood that additional operations can be provided before, during, and after processes shown by FIGS. 1-21, and some of the operations described below can be replaced or eliminated, for additional embodiments of the method. The order of the operations/processes is not limiting and may be interchangeable.

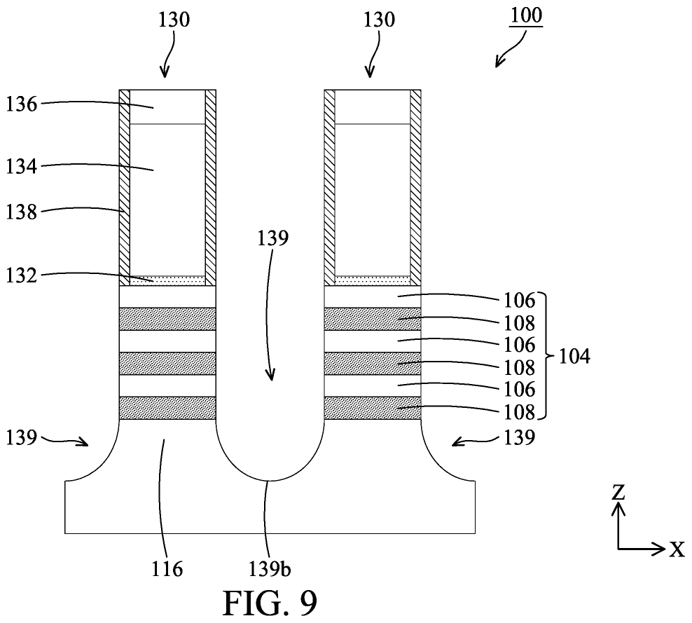

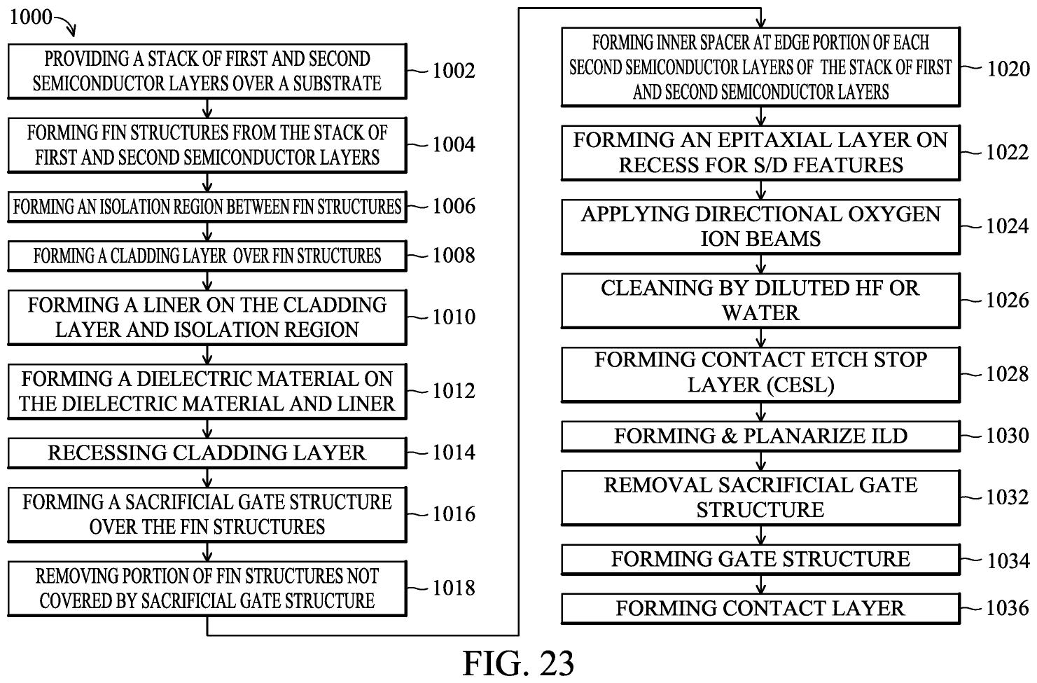

FIGS. 1-8 are perspective views of various stages of manufacturing a semiconductor device structure 100 in accordance with some embodiments. FIG. 23 is a flowchart of a method 1000 for fabricating the semiconductor device 100 according to embodiments of the present disclosure. FIGS. 9-21 schematically illustrate the semiconductor device 100 at various stages of fabrication according to the method 1000. It is understood that additional steps can be provided before, during, and/or after the method 1000, and some of the steps described can be replaced, eliminated, and/or moved around for additional embodiments of the method 1000.

At block 1002, the semiconductor device structure 100 including a stack of semiconductor layers 104 formed over a substrate 101 is provided, as shown in FIG. 1. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In one embodiment, the substrate 101 is made of silicon. In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type impurities). Depending on circuit design, the dopants may be, for example boron for p-type field effect transistors (p-type FETs) and phosphorus for n-type field effect transistors (n-type FETs).

The stack of semiconductor layers 104 includes semiconductor layers made of different materials to facilitate formation of nanosheet channels in a multi-gate device, such as nanosheet FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed parallelly with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. In any case, the second semiconductor layers 108 may have a Ge concentration in a range between about 20 at. % (atomic percentage) and 30 at. %.

The thickness of the first semiconductor layers 106 and the second semiconductor layers 108 may vary depending on the application and/or device performance considerations. In some embodiments, each first and second semiconductor layer 106, 108 may have a thickness in a range between about 5 nm and about 30 nm. Each second semiconductor layer 108 may have a thickness that is equal to, less than, or greater than the thickness of the first semiconductor layer 106. In some embodiments, each first semiconductor layer 106 has a thickness in a range between about 10 nm and about 30 nm, and each second semiconductor layer 108 has a thickness in a range between about 5 nm to about 20 nm. The second semiconductor layers 108 may eventually be removed and serve to define a vertical distance between adjacent channels for the semiconductor device structure 100.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define channels of the semiconductor device structure 100 is further discussed below.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. While three first semiconductor layers 106 and three second semiconductor layers 108 are alternately arranged as illustrated in FIG. 1, it can be appreciated that any number of first and second semiconductor layers 106, 108 can be formed in the stack of semiconductor layers 104, depending on the predetermined number of nanosheet channels for each FET. For example, the number of first semiconductor layers 106, which is the number of channels, may be between 2 and 8.

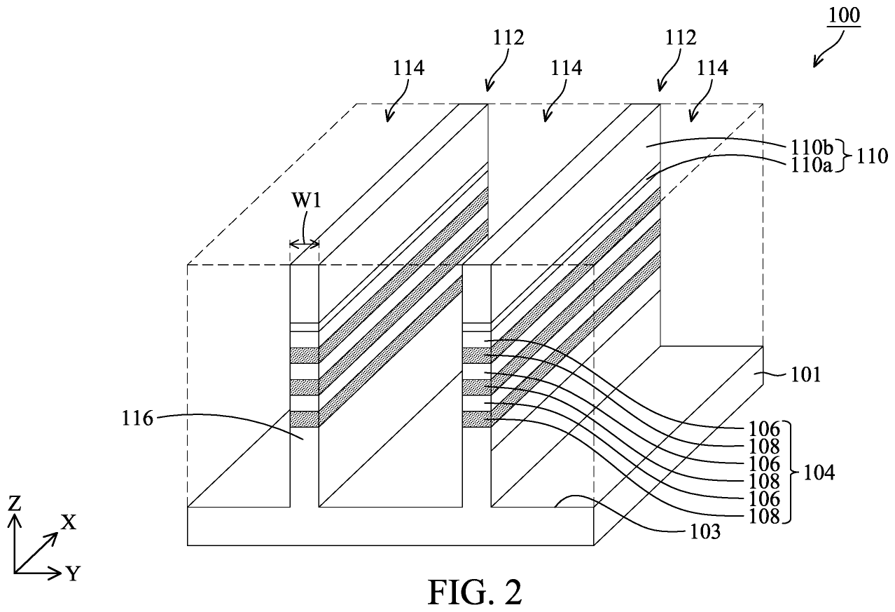

At block 1004, fin structures 112 are formed from the stack of semiconductor layers 104, as shown in FIG. 2. Each fin structure 112 has an upper portion including the semiconductor layers 106, 108 and a well portion 116 formed from the substrate 101. A mask structure 110 is formed over the stack of semiconductor layers 104 prior to forming the fin structures 112. The mask structure 110 may include a pad layer 110a and a hard mask 110b. The pad layer 110a may be an oxygen-containing layer, such as a SiO₂ layer. The hard mask 110b may be a nitrogen-containing layer, such as a Si₃N₄ layer. The mask structure 110 may be formed by any suitable deposition process, such as chemical vapor deposition (CVD) process.

The fin structures 112 may be formed by patterning the mask structure 110 using one or more photolithography processes and etching processes. The etching process can include dry etching, wet etching, reactive ion etching (RIE), and/or other suitable processes. The photolithography process may include double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures 112. In any case, the one or more etching processes form trenches 114 in unprotected regions through the mask structure 110, through the stack of semiconductor layers 104, and into the substrate 101, thereby leaving the plurality of extending fin structures 112. A width W1 of the fin structures 112 along the Y direction may be in a range between about 1.5 nm and about 44 nm, for example about 2 nm to about 6 nm. The trenches 114 may be etched using a dry etch (e.g., RIE), a wet etch, and/or combination thereof. While two fin structures 112 are shown, the number of the fin structures is not limited to two.

FIG. 2 further illustrates the fin structures 112 having substantially vertical sidewalls, such that width of the fin structures 112 are substantially similar and each of the first and second semiconductor layers 106, 108 in the fin structures 112 is rectangular in shape. In some embodiments, the fin structures 112 may have tapered sidewalls, such that a width of each of the fin structures 112 continuously increases in a direction towards the substrate 101. In such cases, each of the first and second semiconductor layers 106, 108 in the fin structures 112 may have a different width and be trapezoidal in shape.

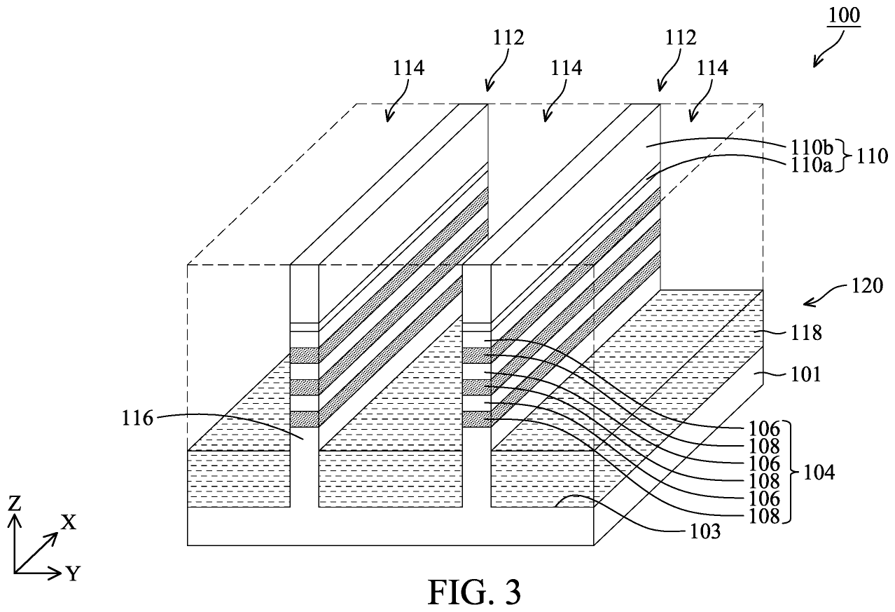

At block 1006, after the fin structures 112 are formed, an insulating material 118 is formed in the trenches 114 between the fin structures 112, as shown in FIG. 3. The insulating material 118 fills the trenches 114 between neighboring fin structures 112 until the fin structures 112 are embedded in the insulating material 118. Then, a planarization operation, such as a chemical mechanical polishing (CMP) process and/or an etch-back process, is performed to expose the top of the fin structures 112. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as low-pressure chemical vapor deposition (LPCVD), plasma enhanced CVD (PECVD) or flowable CVD (FCVD).

Thereafter, the insulating material 118 is recessed to form an isolation region 120. After recessing, portions of the fin structures 112, such as the stack of semiconductor layers 104, may protrude from between neighboring isolation regions 120. The isolation regions 120 may have top surfaces that are flat as illustrated, convex, concave, or a combination thereof. The recess of the insulating material 118 reveals the trenches 114 between the neighboring fin structures 112. The isolation region 120 may be formed using a suitable process, such as a dry etching process, a wet etching process, or a combination thereof. In one embodiment, the isolation regions 120 are formed using dilute hydrofluoric acid (dHF), which is selective to the insulating material 118 over the stack of semiconductor layers 104. Upon completion of recessing, a top surface of the insulating material 118 may be level with or below a surface of the second semiconductor layers 108 in contact with the well portion 116 formed from the substrate 101.

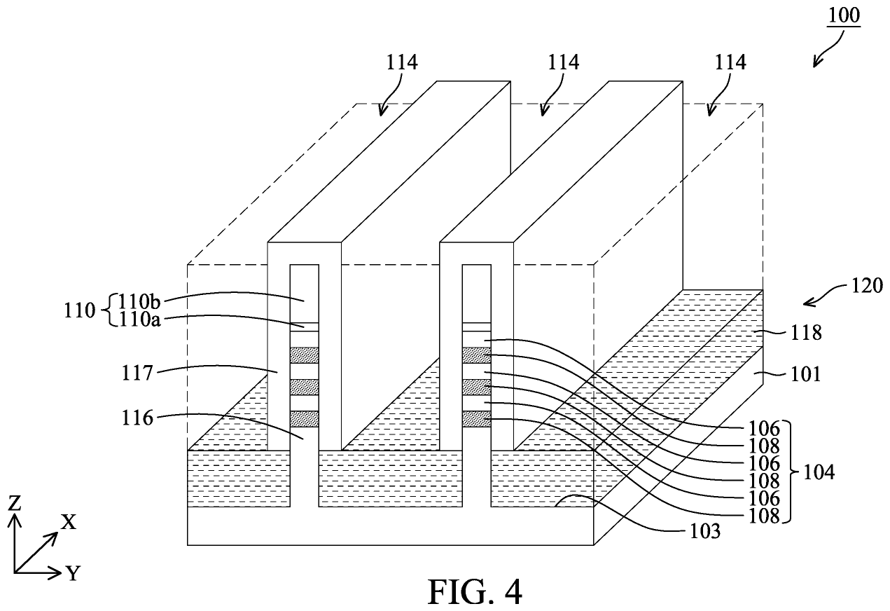

At block 1008, a cladding layer 117 can be formed by an epitaxial process over exposed portion of the fin structures 112, as shown in FIG. 4. In some embodiments, a semiconductor liner (not shown) may be first formed over the fin structures 112, and the cladding layer 117 is then formed over the semiconductor liner. The semiconductor liner may be diffused into the cladding layer 117 during the formation of the cladding layer 117. In either case, the cladding layer 117 is in contact with the stack of semiconductor layers 104. In some embodiments, the cladding layer 117 and the second semiconductor layers 108 include the same material having the same etch selectivity. For example, the cladding layer 117 and the second semiconductor layers 108 may be or include SiGe. The cladding layer 117 and the second semiconductor layers 108 may be removed subsequently to create space for the subsequently formed gate electrode layer.

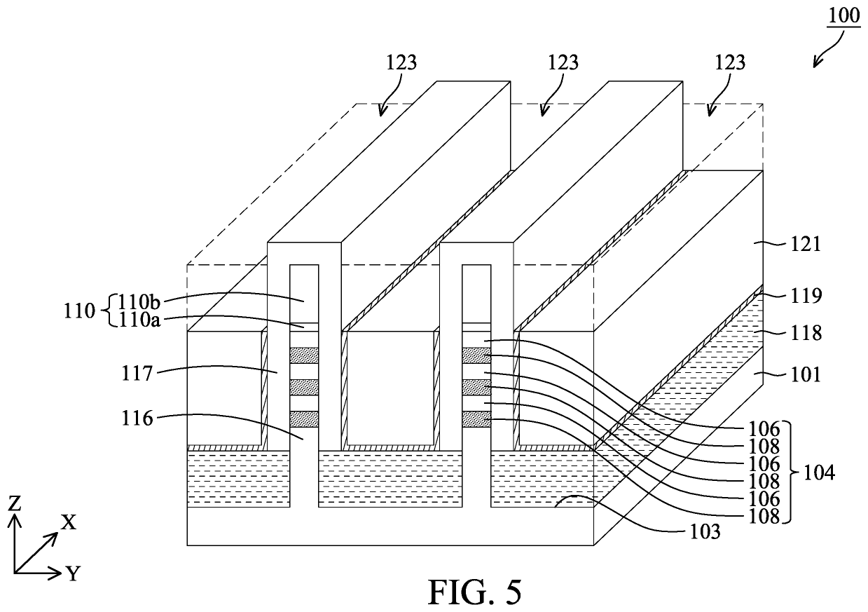

At block 1010, a liner 119 is formed on the cladding layer 117 and the top surface of the insulating material 118, as shown in FIG. 5. The liner 119 may include a material having a k value lower than 7, such as SiO₂, SiN, SiCN, SiOC, or SiOCN. The liner 119 may be formed by a conformal process, such as an ALD process. A dielectric material 121 is then formed in the trenches 114 (FIG. 4) and on the liner 119. The dielectric material 121 may be an oxygen-containing material, such as an oxide, formed by FCVD. The oxygen-containing material may have a k value less than about 7, for example less than about 3. A planarization process, such as a CMP process, may be performed to remove portions of the liner 119 and the dielectric material 121 formed over the fin structures 112. The portion of the cladding layer 117 disposed on the hard mask 110b is exposed after the planarization process.

Next, the liner 119 and the dielectric material 121 are recessed to the level of the topmost first semiconductor layer 106. For example, in some embodiments, after the recess process, the top surfaces of the liner 119 and the dielectric material 121 may be level with a top surface of the uppermost first semiconductor layer 106. The recess processes may be selective etch processes that do not substantially affect the semiconductor material of the cladding layer 117. As a result of the recess process, trenches 123 are formed between the fin structures 112.

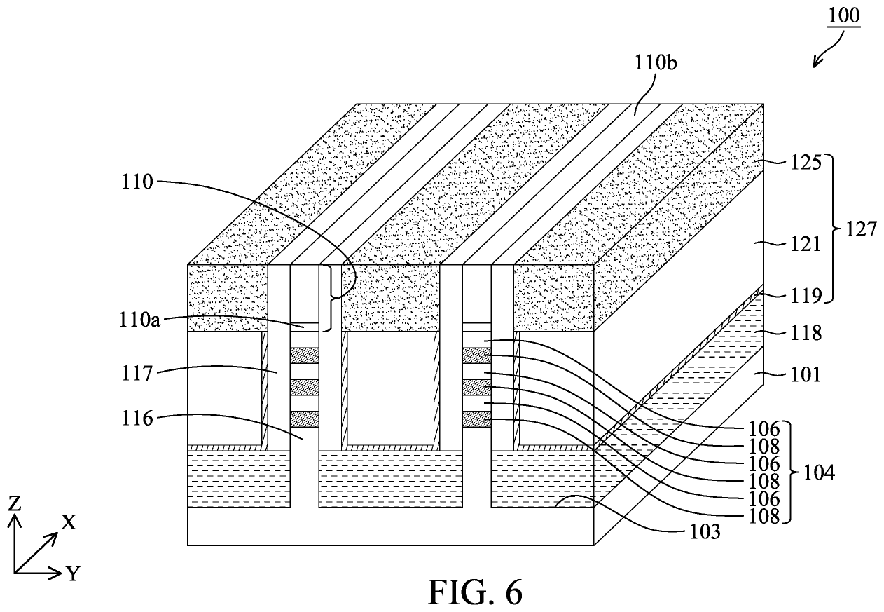

At block 1012, a dielectric material 125 is formed in the trenches 123 (FIG. 5) and on the dielectric material 121 and the liner 119, as shown in FIG. 6. The dielectric material 125 may include SiO, SiN, SiC, SiCN, SiON, SiOCN, AlO, AlN, AlON, ZrO, ZrN, ZrAlO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the hard mask 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127 or a hybrid fin. The dielectric feature 127 serves to separate subsequent formed source/drain (S/D) epitaxial features and adjacent gate electrode layers.

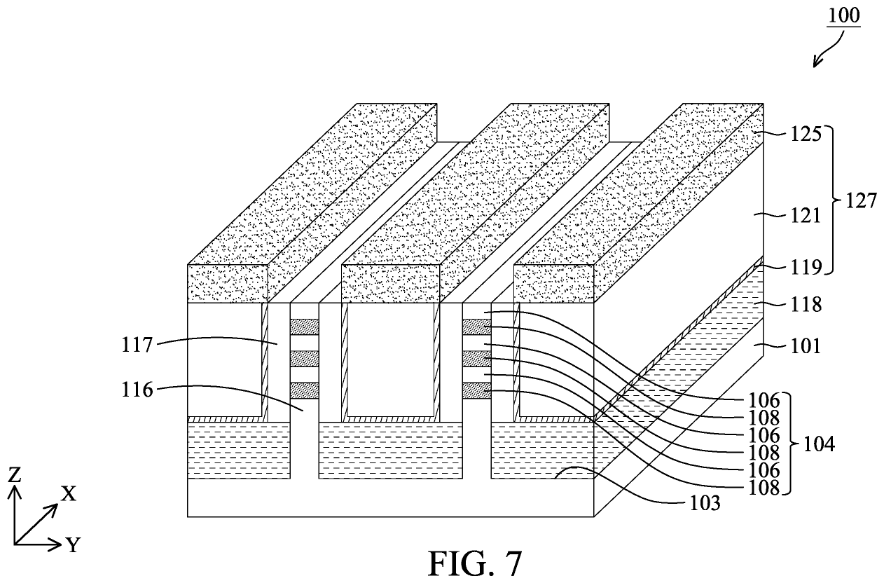

At block 1014, the cladding layers 117 are recessed, and the mask structures 110 are removed, as shown in FIG. 7. The recess of the cladding layers 117 may be performed by any suitable process, such as dry etch, wet etch, or a combination thereof. The recess process may be controlled so that the remaining cladding layers 117 are substantially at the same level as the top surface of the uppermost first semiconductor layer 106 in the stack of semiconductor layers 104. The etch process may be a selective etch process that does not substantially affect the dielectric material 125. The removal of the mask structures 110 may be performed by any suitable process, such as dry etch, wet etch, or a combination thereof.

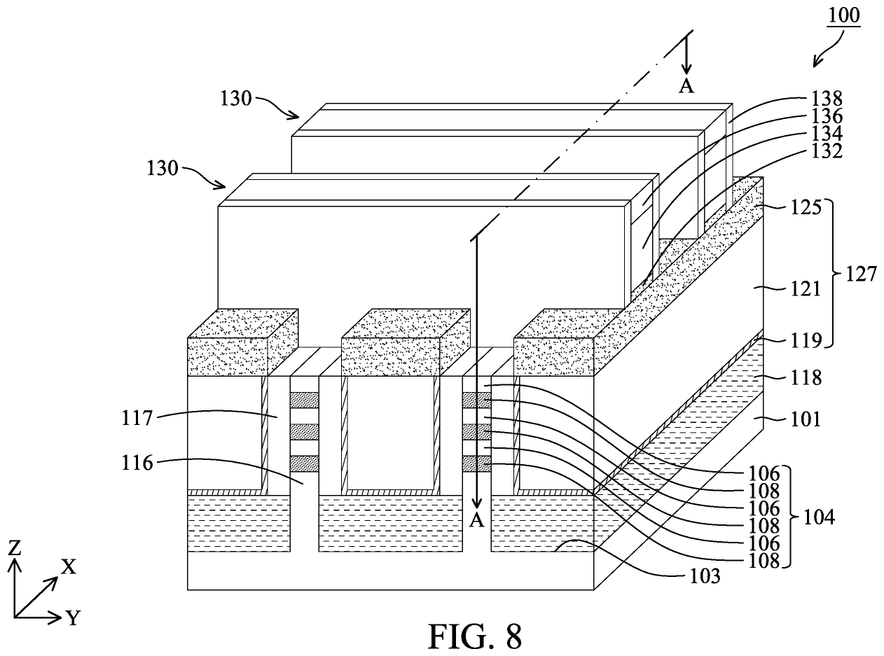

At block 1016, one or more sacrificial gate structures 130 (only two is shown) are formed over the semiconductor device structure 100, as shown in FIG. 8. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. While two sacrificial gate structures 130 are shown, more or less sacrificial gate structures 130 may be arranged along the X direction in some embodiments.

Next, gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as silicon oxide, silicon nitride, silicon carbide, silicon oxynitride, SiCN, silicon oxycarbide, SiOCN, and/or combinations thereof.

In some embodiments where the cladding layers 117 and the dielectric features 127 are not present, portions of the sacrificial gate structures 130 and the gate spacers 138 are formed on the insulating material 118, and gaps are formed between exposed portions of the fin structures 112.

FIGS. 9-21 are cross-sectional side views of various stages of manufacturing the semiconductor device structure 100 taken along cross-section A-A of FIG. 8, in accordance with some embodiments. Cross-section A-A is in a plane of the fin structure 112 along the X direction. At block 1018, exposed portions of the stacks of semiconductor layers 104 of the fin structures 112, exposed portions of the cladding layers 117, and a portion of the exposed dielectric material 125 not covered by the sacrificial gate structures 130 and the gate spacers 138 are removed to form recess 139 for the S/D features, as shown in FIG. 9. The removal of the layers may be done by using one or more suitable etch processes, such as dry etch, wet etch, or a combination thereof. The one or more etch processes may be performed until the well portions 116 are exposed. The exposed portions of the fin structures 112 may be recessed to a level at the bottom surface of the second semiconductor layer 108 in contact with the well portion 116 of the substrate 101. In some embodiments, the etch process is performed such that the bottom 139b of the recess 139 is at an elevation below an interface defined by the bottommost second semiconductor layer 108 and the well portion 116.

At block 1020, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon and/or SiGe having lower germanium concentration than the second semiconductor layers 108, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

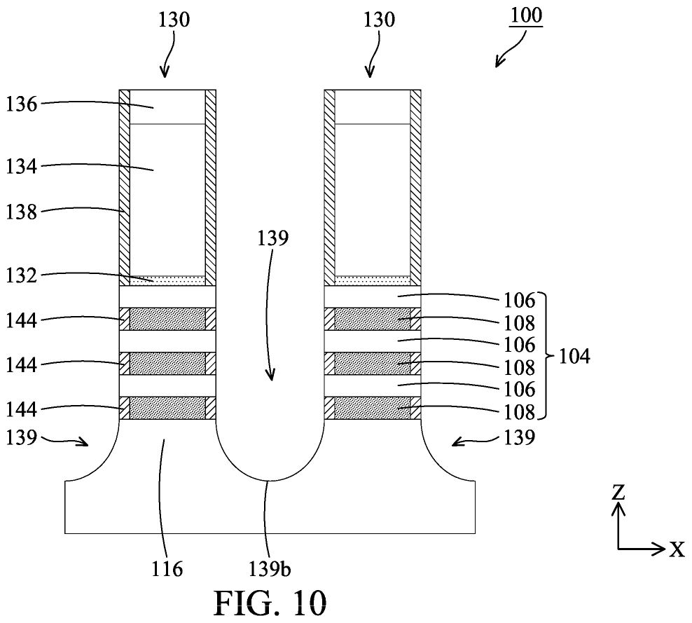

After removing edge portions of each second semiconductor layers 108, a dielectric layer is deposited in the cavities to form dielectric spacers (or so-called inner spacer) 144, as shown in FIG. 10. The dielectric spacers 144 may be made of SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

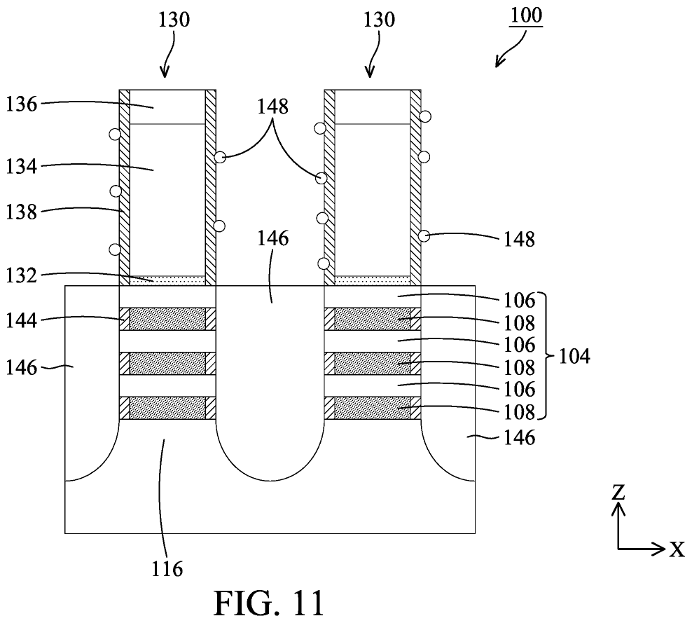

At block 1022, a source/drain (S/D) feature is formed in the S/D regions between the neighboring stacks of semiconductor layers 104. The S/D feature includes an epitaxial layer 146 as shown in FIG. 11. The S/D features may be the S/D regions, for example, one of a pair of S/D epitaxial features located on one side of the sacrificial gate structures 130 may be a source region, and the other of the pair of S/D epitaxial features located on the other side of the sacrificial gate structures 130 may be a drain region. A pair of S/D epitaxial features includes a source epitaxial feature and a drain epitaxial feature connected by the channel layers (i.e., the first semiconductor layers 106). In this disclosure, a source and a drain are interchangeably used, and the structures thereof are substantially the same.

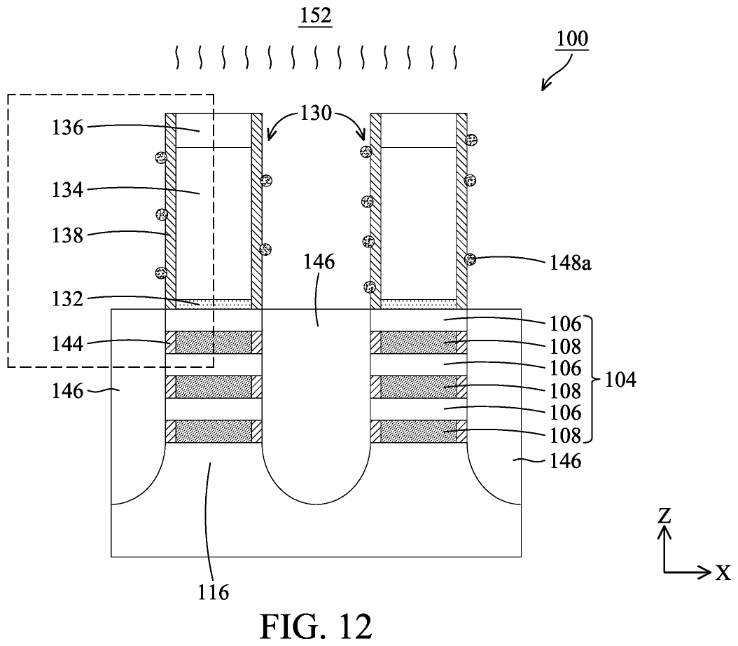

Referring back to FIG. 11, the epitaxial layer 146 is formed on exposed surfaces of the recess 139 (FIG. 10). The epitaxial layer 146 is selectively formed on a semiconductor surface of the first semiconductor layers 106 and the well portions 116, while a dielectric surface of the sacrificial gate structures 130 (e.g., mask layers 136 and gate spacers 138) remains exposed. The growth of the epitaxial layer 146 may extend to fill the recesses 139 and to cover the surface of the dielectric spacers 144 as shown in FIG. 12.

The epitaxial layer 146 may include or be formed of silicon, germanium, or silicon germanium. Depending on the conductivity type of the S/D features to be grown thereon, n-type or p-type dopants may be added. For example, the epitaxial layer 146 at a n-type device region may include silicon doped with n-type dopants, such as phosphorous, antimony, or arsenic, and the epitaxial layer 146 at a p-type device region may include silicon doped with p-type dopants, such as boron or gallium. Exemplary epitaxial layers 146 may include boron-doped silicon (Si:B), phosphorous doped silicon (Si:P), gallium doped silicon (Si:Ga), boron-doped germanium (Ge:B), boron-doped silicon germanium (SiGe:B), or gallium-doped silicon germanium (SiGe:Ga).

In cases where silicon germanium is used for p-type S/D features, the epitaxial bottom layer 146 may have an atomic percentage of Ge in a range between about 0 at. % and 80 at. %, such as about 40 at. % to about 60 at. %, for channel stress boosting with quality. The epitaxial layer 146 may have a dopant concentration in a range of about 5E19 atoms/cm³ and about 5E21 atoms/cm³. The epitaxial layer 146 used at the n-type S/D features may have a dopant concentration in a range of about 5E19 atoms/cm³ and about 5E21 atoms/cm³. In most cases, the dopants may be evenly distributed in the epitaxial layer 146 (e.g., constant distribution) or gradually distributed along the thickness of the epitaxial layer 146 (e.g., gradient distribution). For example, the dopants in the epitaxial layer 146 may have a first dopant concentration at and/or near the surface, and a second dopant concentration at an interface of the epitaxial layer 146 and the first semiconductor layer 106, wherein the first dopant concentration is greater than the second dopant concentration. Alternatively, the dopants may be controlled so that the first dopant concentration is lower than the second dopant concentration.

In some embodiments, the epitaxial layer 146 may be deposited such that a top of the epitaxial layer 146 may be at an elevation higher or equal to a top of the topmost first semiconductor layers 106. The epitaxial layer 146 may be formed using any suitable deposition process, such as CVD, cyclic deposition etch (CDE) epitaxy process, selective etch growth (SEG) process, ALD, PEALD, molecular beam epitaxy (MBE), or any combination thereof. In some embodiments, the first semiconductor layers 106 may be exposed to silicon-containing precursor(s) and n-type or p-type dopant-containing precursor(s) in a process chamber to form the epitaxial layer 146. The process conditions of the growth process are configured in accordance with the crystal planes of the first semiconductor layer 106 and the substrate 101 to promote formation of the epitaxial layer 146. The dopants in the epitaxial layers 146 may be added during the formation of the epitaxial bottom layers 146, and/or after the formation of the epitaxial layers 146 by an implantation process.

In one exemplary embodiment where the epitaxial layer 146 includes boron-doped silicon germanium, the epitaxial layer 146 may be formed by heating the semiconductor device structure 100 to a temperature of about 400 degrees Celsius to about 750 degrees Celsius, such as about 520 degrees Celsius to about 620 degrees Celsius, maintaining chamber pressure at about 10 Torr to about 300 Torr, such as about 20 Torr to about 80 Torr, and exposing the exposed surfaces of the semiconductor device structure 100 to a gas mixture including at least a silicon-containing precursor, a germanium-containing precursor, and a boron-containing precursor. Suitable silicon-containing precursor may include, but is not limited to, silane (SiH₄), disilane (Si₂H₆), trisilane (Si₃H₈), tetrasilane (Si₄H₁₀), dimethylsilane ((CH₃)₂SiH₂), methylsilane (SiH(CH₃)₃), dichlorosilane (SiH₂Cl₂, DCS), trichlorosilane (SiHCl₃, TCS), or the like. Suitable germanium-containing precursor may include, but is not limited to, germane (GeH₄), germanium tetrachloride (GeCl₄), digermane (Ge₂H₆), trigermane (Ge₃H₈), or germylsilane (GeH₆Si) or the like. Suitable gases for the boron-containing precursor may include, but are not limited to, borane (BH₃), diborane (B₂H₆), boron trichloride (BCl₃), triethyl borate (TEB), borazine (B₃N₃H₆), or an alkyl-substituted derivative of borazine, or the like. A diluent/carrier gas, such as hydrogen (H₂) and/or argon (Ar), may be used along with the precursors for the epitaxial layer 146. In one embodiment, the epitaxial layer 146 is formed by DCS, GeH₄, and B₂H₆. In one embodiment, the epitaxial layer 146 is formed by DCS, GeH₄, and BCl₃. In some cases, the epitaxial layer 146 may be deposited by a deposition-etch-deposition process for improving void-free gap-filling. In such cases, an etch gas, such as HCl or Cl₂ may be further introduced into the reaction chamber. The formation of the epitaxial layer 146 may be performed in a CVD based reaction chamber.

During formation of the epitaxial layer 146, the precursor for the epitaxial growth process traveling towards the bottom 139b may bombard towards the exposed surface of the gate spacers 138 to cause epitaxial nodules 148 growing on the gate spacers 138 above the S/D region as shown in FIG. 11. The nodules 148 may be removed by an in-situ cleaning process using HCl. The mechanism of removing the epitaxial nodules may be represented by the following formula:

HCl→H+Cl

Si+2Cl₂→SiCl₄

As the composition between Cl and Si not only occurs to the nodules 148, but also occurs to the epitaxial layer 146. The loss of the S/D features may have occurred before the nodules 148 have completely removed. An alternative way to remove the nodules 148 includes an ex-situ (hydrogen) H-radical cleaning process. However, the H-radical cleaning process is often effective to remove the n-type nodules. The p-type epitaxial layer such as SiGeB layer may not be effectively removed using the H-radical cleaning process, particularly for the epitaxial layer with higher Ge concentration. Although the n-type nodules may be removed by the H-radical cleaning process, with the relatively smaller sizes, hydrogen may easily penetrate into the epitaxial layer 146 to cause lattice distortion in the n-type epitaxial layer. The same issues also occur to epitaxial layers formed of other materials.

To effectively remove the nodules 148 without causing loss of the S/D feature, a two-step cleaning process is provided according to some embodiments. The two-step cleaning process will be discussed with reference to the cross-sectional views of the semiconductor device structure 100 in FIGS. 12-21 and the process flow in FIG. 23. The first step of the two-step cleaning process includes an oxidation process performed on the nodules 148, and the second step uses a solution to wash away oxidized materials. As shown in FIG. 12, directional oxygen ion beams are applied to the nodules 148 for oxidizing the nodules at block 1024 of FIG. 23. The directional oxygen ion beams 150 may be generated from CO source. For example, the oxygen beams may be generated by applying either radio frequency (RF) or microwave radiation to discharge a plasma containing CO according to some embodiments. The oxygen ion beams 150 are applied with a tilt angle with respect to the surface of the gate spacers 138. The tilt angle may be adjusted based on the aspect ratio of the opening between the neighboring sacrificial gates 130 to avoid the oxygen ion beams incident on the epitaxial layer 146.

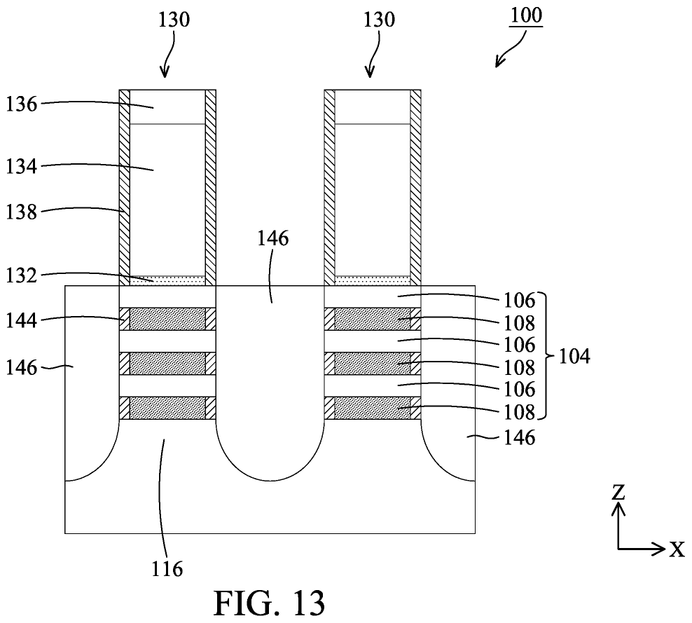

The oxidization process may be applied to both n-type nodules and p-type nodules. For example, the n-type nodules 148 may be oxidized into SiO 148a and the p-type nodules 148 may be oxidized into SiGeO 148a as shown in FIG. 12. At block 1026 of FIG. 23, the oxidized nodules 148a may then be washed away by diluted HF solution 152. For example, the HF solution 152 may have a HF to water ratio of about 1:500 for removing the oxidized n-type nodules 148a. The HF solution 152 may be further diluted for removing the p-type oxidized nodule 148a. In some embodiments, water may also be used to remove the p-type oxidized nodules 148a. FIG. 13 shows the semiconductor device 100 after the nodules 148 have been removed by the two-step cleaning process.

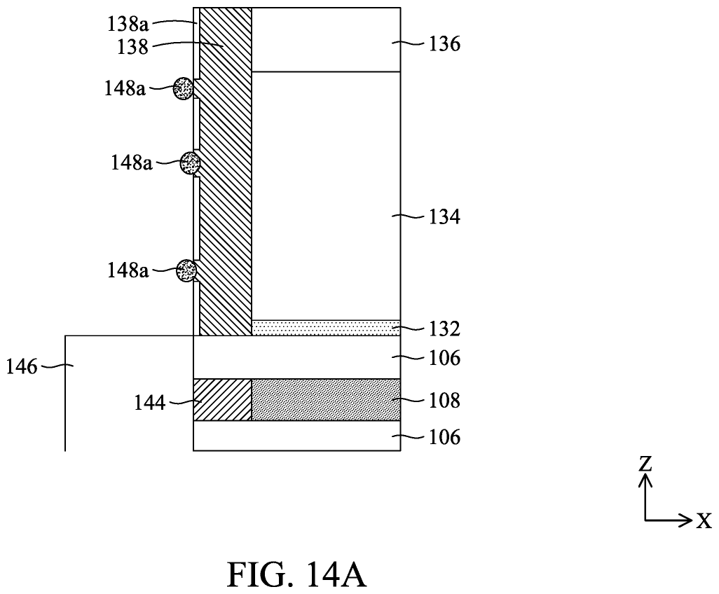

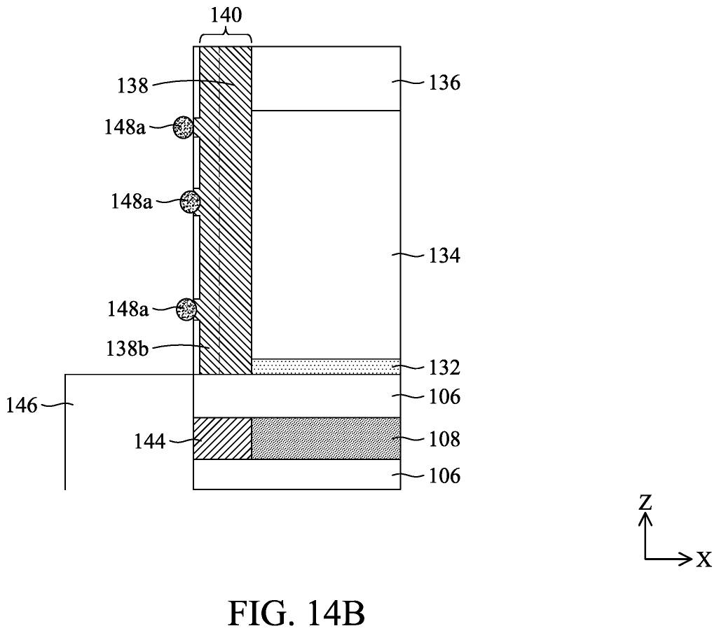

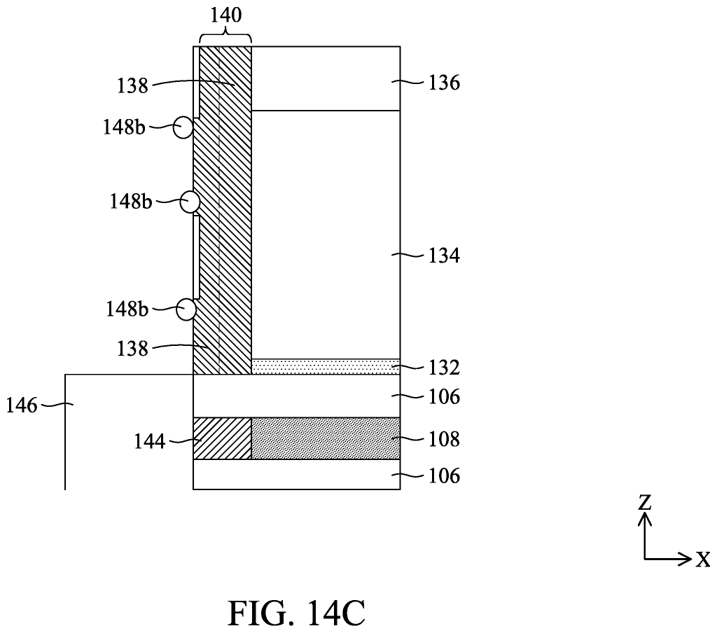

FIG. 14A-14C show an enlarged view of a part framed by the dash-line as shown in FIG. 12 according to different embodiments. As shown in FIG. 14A, the nodules 148 are oxidized by application of oxygen ion beams 150. As portions of the surface of the gate spacers 138 are also exposed to the oxygen ion beams 150, the exposed gate spacers 138 may also be oxidized and converted into oxidized portion 138a during oxidation of the nodules 148. The oxidation depth of the oxidized portion 138a varies according to the extraction energy for generating the oxygen ions from the ion beam source, for example, a CO source. For example, the oxidation depth may range from about 3 Å to about 50 Å. When the gate spacers 138 are made of SiON, the oxidation process increases the oxygen content of SiON to an extent that the oxidized portions 138a may be subsequently removed or washed away by the diluted HF or water for removing the oxidized nodules 148a.

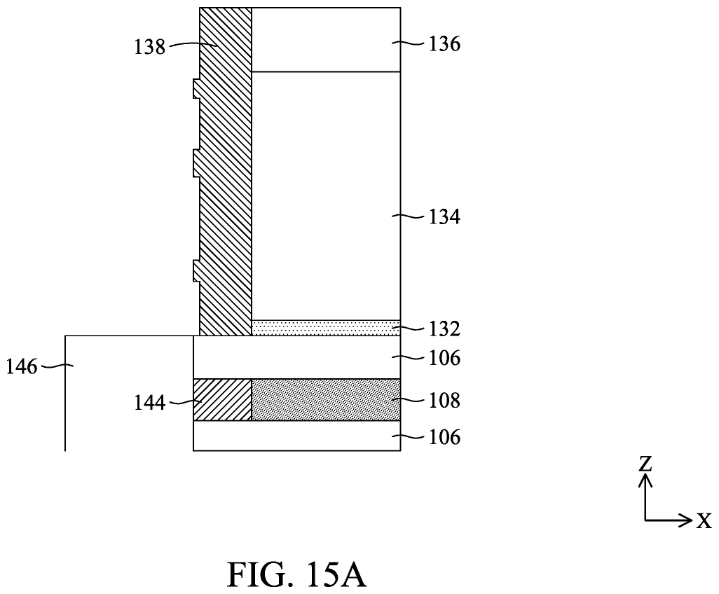

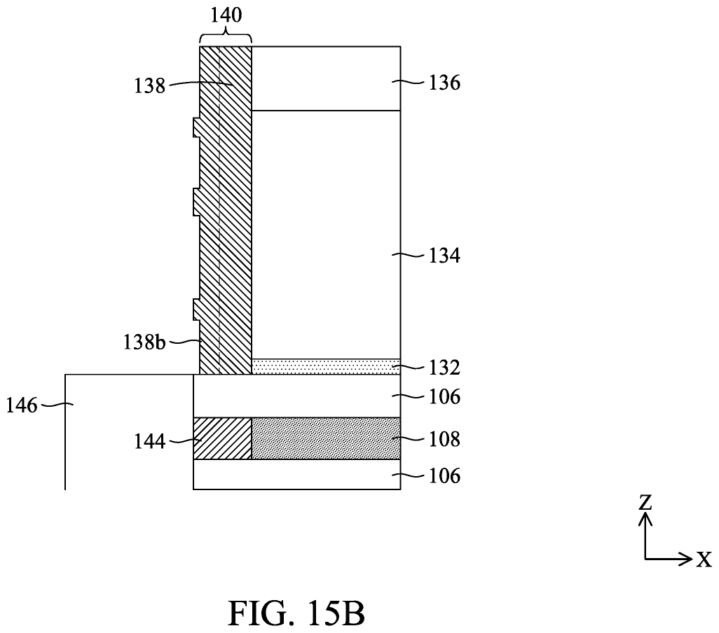

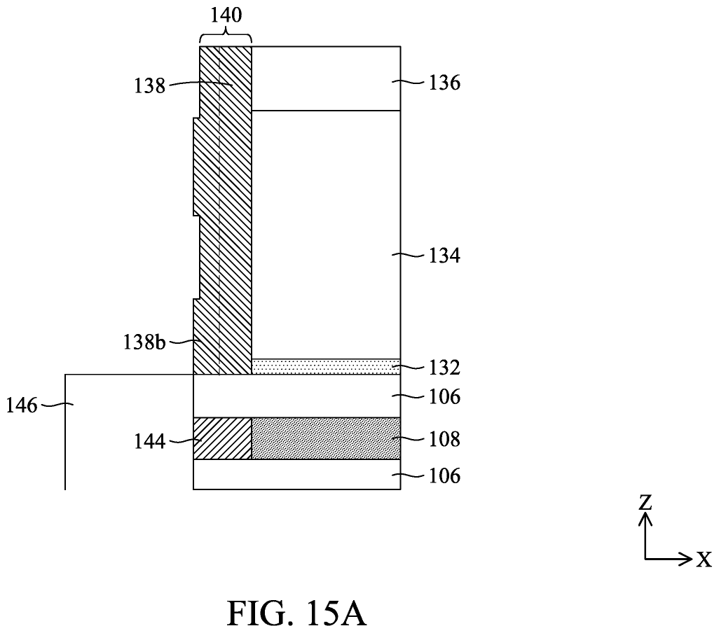

In some embodiments, the gate spacers may include a two-layer structure 140 as shown in FIGS. 14B-14C. The two-layer structure 140 includes a first layer 138, that is, the original gate spacer 138 formed on the sidewalls of sacrificial gate electrode 134, and a second layer 138b formed during deposition of the dielectric spacers 144. Each of the first layer 138 and second layer 138b may be made of low-k dielectric materials such as silicon oxide, silicon nitride, silicon carbide, silicon oxynitride, SiCN, silicon oxycarbide, SiOCN, and/or combinations thereof. As shown in FIG. 14B, portions of the second layer 138b exposed to the oxygen ion beams 150 may be oxidized while oxidizing the nodules 148. The oxidized portions of the gate spacers 140 may be removed or washed away while cleaning the oxidized nodules 148a using dilute HF solution or water as shown in FIG. 15B.

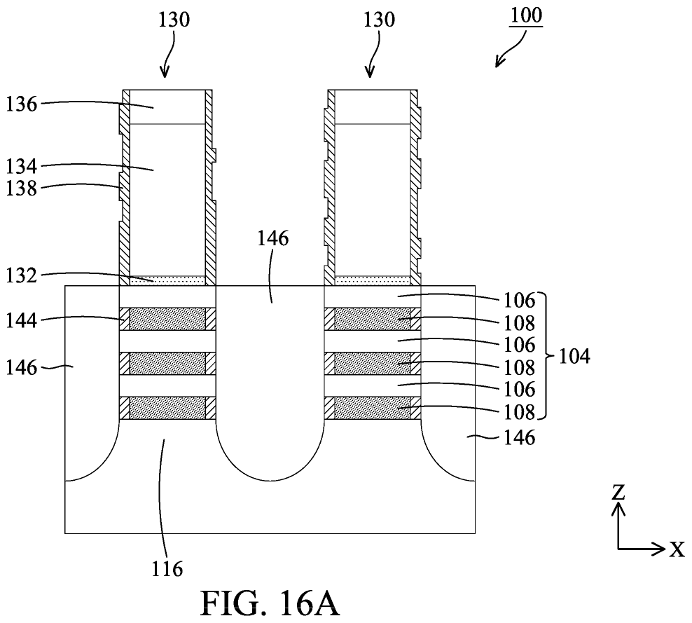

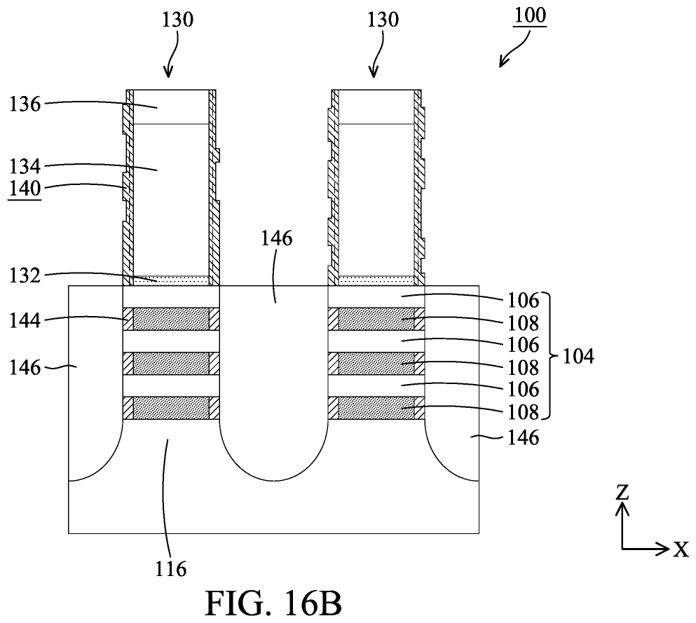

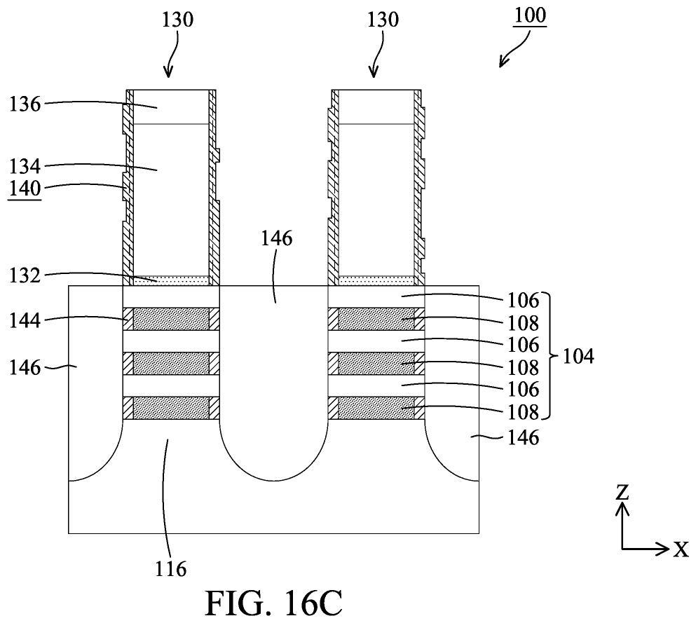

In some embodiments, some of the exposed portions of the gate dielectric spacers 138 (or 138b) may be unoxidized or insufficiently oxidized to be removed in the subsequent cleaning process using diluted HF solution or water as shown in FIG. 15C. FIGS. 15A-15C illustrate a stage corresponding to the semiconductor device structure 100 of FIGS. 14A-14C after removal of the nodules 148. As can be seen, the surface of the gate dielectric layers 138 (140) is roughened as portions of the gate dielectric layers 138 (140) not covered by the nodules 148 are removed simultaneously, while the portions of the gate dielectric layers 138 (140) under the nodules 148 are not etched or removed at a slower etch rate. As a result, the gate dielectric spacers 138 (140) are formed with surface roughness. The surface roughness may be considered as a distance measuring between a bottom of the recessed portion and the unremoved portion of the surface of the gate dielectric layers 138 (140). In some embodiments, the surface roughness may be measured in Angstroms and may have a range from about 3-4 Å to about 5-6 Å. FIGS. 16A-16C show the semiconductor device structure 100 with the roughness of the gate spacers 138 (140) as shown in FIGS. 15A-15C, respectively.

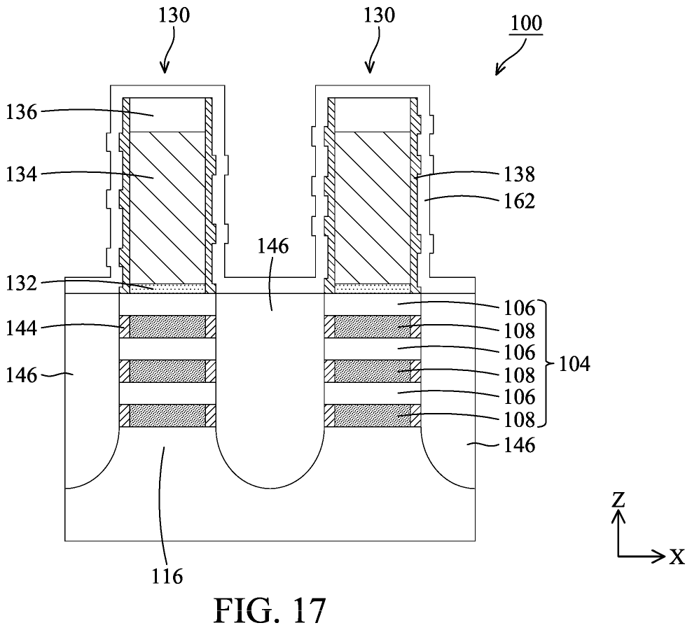

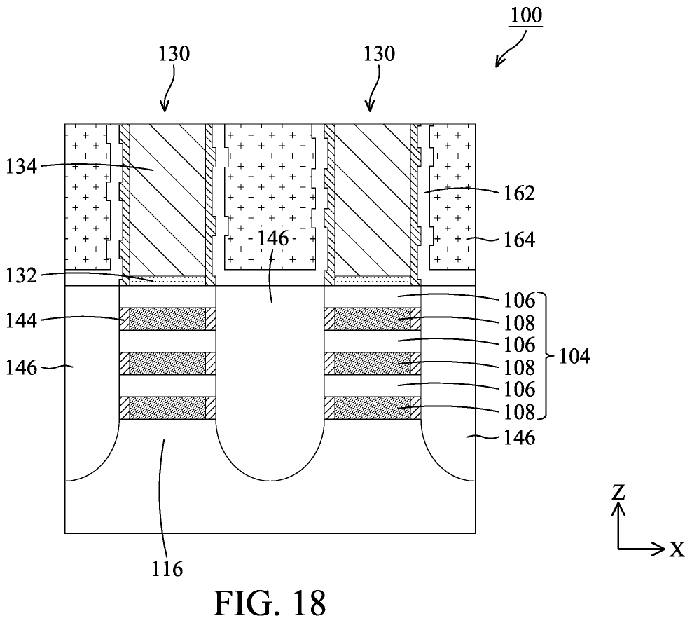

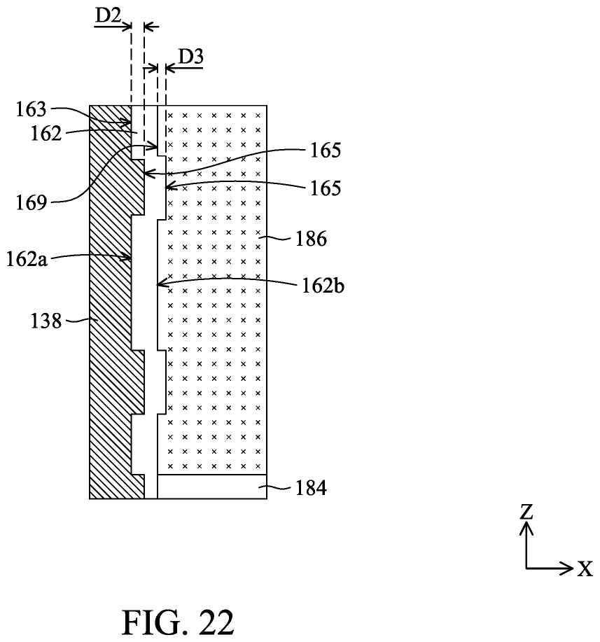

FIGS. 17-21 are cross-sectional views showing various stages of manufacturing the semiconductor device 100 as shown in FIG. 16A after the removal of the nodules 148. The same processes may apply to the semiconductor devices 100 with dual-layer gate spacers 140 as shown in FIGS. 16B and 16C. At block 1028, a contact etch stop layer (CESL) 162 is conformally formed on the exposed surfaces of the semiconductor device structure 100, as shown in FIG. 17. The CESL 162 covers the top surfaces of the sacrificial gate structure 130, the insulating material 118, the epitaxial S/D features 146, and the exposed surface of the stack of semiconductor layers 104. The CESL 162 may have a surface profile in accordance with the surface profile of the gate spacers 138 (140), as will be discussed in more detail in FIG. 22. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, as shown in FIG. 18, an interlayer dielectric (ILD) layer 164 is formed on the CESL 162 over the semiconductor device structure 100 at block 1030. The materials for the ILD layer 164 may include compounds comprising Si, O, C, and/or H, such as silicon oxide, TEOS oxide, SiCOH and SiOC. Organic materials, such as polymers, may also be used for the ILD layer 164. The ILD layer 164 may be deposited by a PECVD process or other suitable deposition technique. A planarization process such as CMP is performed on the until the gate electrode layer 134 is exposed.

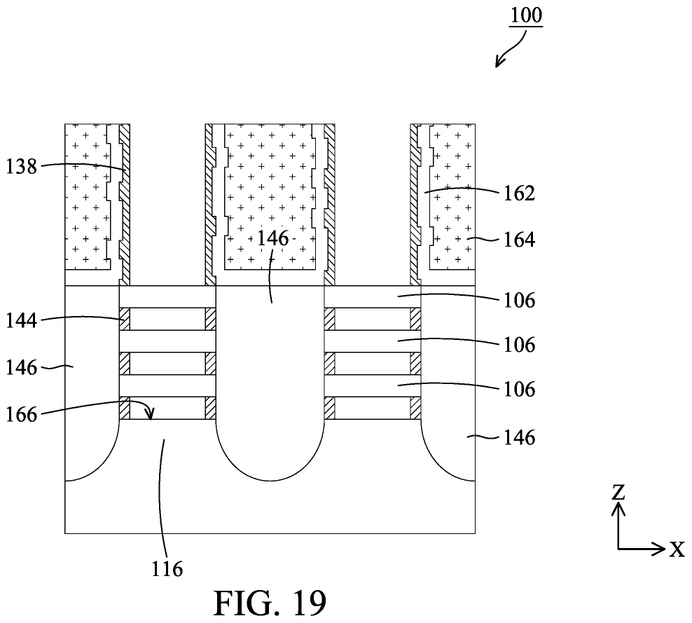

At block 1032, the sacrificial gate structure 130 and the second semiconductor layers 108 are sequentially removed, as shown in FIG. 19. The removal of the sacrificial gate structure 130 and the semiconductor layers 108 forms an opening 166 between gate spacers 138 and between adjacent first semiconductor layers 106 (see FIG. 19). The ILD layer 164 protects the epitaxial S/D features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof.

The removal of the sacrificial gate structure 130 exposes the first semiconductor layers 106 and the second semiconductor layers 108. An etch process, which may be any suitable etch processes, such as dry etch, wet etch, or a combination thereof, is then performed to remove the second semiconductor layers 108 and expose the dielectric spacers 144. The etch process may be a selective etch process that removes the second semiconductor layers 108 but not the gate spacers 138, the dielectric spacers 144, the ILD layer 164, the CESL 162, and the first semiconductor layers 106. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants. After the etch process, a portion of the first semiconductor layers 106 not covered by the dielectric spacers 144 is exposed through the opening 166.

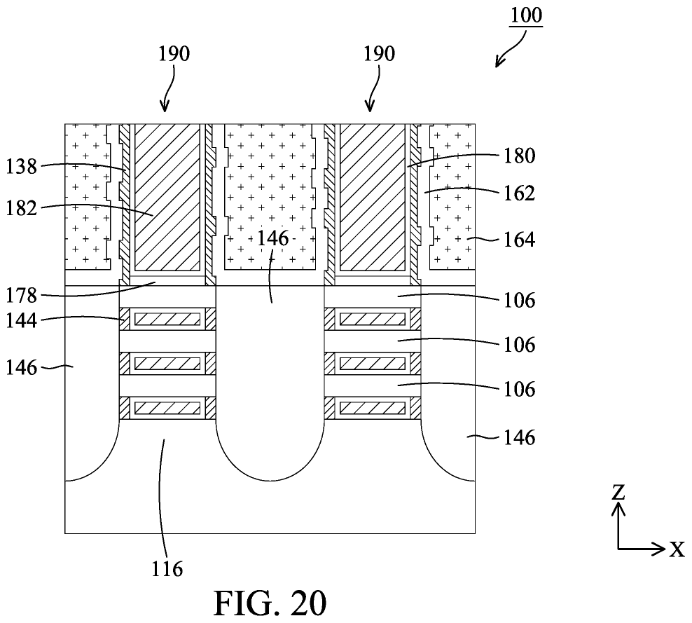

At block 1034, replacement gate structures 190 are formed, as shown in FIG. 20. Each replacement gate structure 190 may include an interfacial layer (IL) 178, a gate dielectric layer 180, and a gate electrode layer 182. The interfacial layer (IL) 178 is formed to surround exposed surfaces of the first semiconductor layers 106 along the channel regions. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). The IL 178 may be formed by CVD, ALD, a clean process, or any suitable process. Next, the gate dielectric layer 180 is formed on the exposed surfaces of the semiconductor device structure 100 (e.g., on the IL 178, sidewalls of the gate spacers 138, the top surfaces of the first ILD layer 164, the CESL 162, and the dielectric spacers 144). The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The gate dielectric layer 180 may be a conformal layer formed by a conformal process, such as an ALD process, a PECVD process, a molecular-beam deposition (MBD) process, or the like, or a combination thereof.

After formation of the IL 178 and the gate dielectric layer 180, the gate electrode layer 182 is formed on the gate dielectric layer 180. The gate electrode layer 182 filles the openings 166 and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

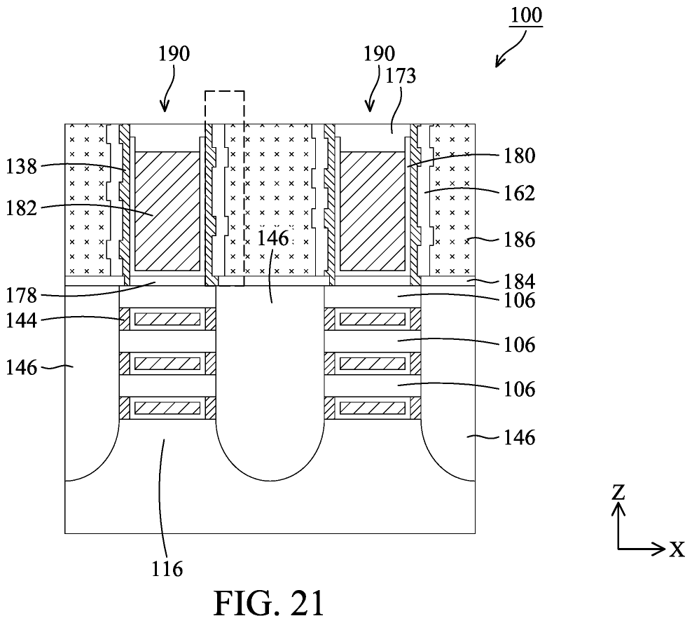

At block 1036, the gate electrode layer 182 may be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the ILD layer 164. A self-aligned contact layer 173 is formed over the gate electrode layer 182 and the gate dielectric layer 180 between the gate spacers 138, as shown in FIG. 21. The self-aligned contact layer 173 may be a dielectric material having an etch selectivity relative to the ILD layer 164. In some embodiments, the self-aligned contact layer 173 includes silicon nitride. Then, contact openings are formed through the ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. The silicide layer 184 may include a metal or metal alloy silicide, and the metal includes a noble metal, a refractory metal, a rare earth metal, alloys thereof, or combinations thereof. Next, a conductive material is formed in the contact openings and form the S/D contacts 186, as shown in FIG. 21. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

FIG. 22 is an enlarged view of a region within a dash-line frame as shown in FIG. 21. As shown, not only the gate spacer 138 has an uneven or roughened surface after removal of the nodules 148, the CESL layer 162 conformal to the gate spacer 138 also has uneven surfaces at both sides thereof. In some embodiments, the CESL layer 162 has a first surface 162a and a second surface 162b opposing the first surface 162a. The first surface 162a is in contact with the gate spacer 138, and the second surface 162b is in contact with the S/D contact 186. In some embodiments, a portion of the first surface 162a and a portion of the gate spacer 138 define a first interface 163, and a portion of the first surface 162a and a portion of the gate spacer 138 define a second interface 165 that is offset from the first interface 163 by a distance D2. Likewise, a portion of the second surface 162b and a portion of the S/D contact 186 define a third interface 167, and a portion of the second surface 162b and a portion of the S/D contact 186 define a fourth interface 169 that is offset from the third interface 167 by a distance D3.

Subsequent processes may be performed on the semiconductor device structure 100 to complete fabrication of a semiconductor device made of as desired. For example, the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features is connected to a backside power rail (e.g., positive voltage VDD or negative voltage VSS) through the backside contacts.

The current disclosure provides a method for removing the undesired nodules formed on the gate spacer during formation of the epitaxial S/D features. The method uses directional oxygen ion beams to oxidize the nodules. The directional oxygen ion beams are applied with a tilt angle with respect to the surface of the gate spacer. The tilt angle may be controlled based on the aspect ratio of the opening between the neighboring gate structures to prevent the epitaxial S/D features to be oxidized with the oxygen ions. Therefore, the epitaxial S/D features loss can be prevented. Depending on the conductive types, the oxidized nodules can then be easily removed or washed away by diluted HF solution or water. As portions of the gate spacers are exposed to the oxygen ion beams, at least a part of the exposed portions of the gate spacers may also be oxidized and removed by the HF solution. This results in a roughened surface of the gate spacers. The roughness of the roughened surface depends on the extraction energy used for generating the ion beams from the oxygen ion source.

According to some embodiments, a method is provided. The method includes forming a plurality of stacks of semiconductor layers. Each of the stacks includes a plurality of first semiconductor layers and a plurality of second layers alternately stacked with each other. A gate electrode structure is then formed on each of the stacks of semiconductor layers, each of the gate electrode structures including a gate spacer. An epitaxial layer is formed in an opening between each pair of neighboring stacks of semiconductor layers. After formation of the epitaxial layer, oxygen ion beams are applied to the gate spacer with a tilt angle to form oxidized materials on the gate spacers with a tilt angle. The oxidized materials are then removed by diluted HF solution.

According to another embodiment, a method for removing nodules formed on a gate spacer during formation of an epitaxial S/D feature in a semiconductor device structure is provided. The method includes applying directional oxygen ion beams to oxidize the nodules with a tilt angle adjusted to prevent oxygen ions applied to the epitaxial S/D features and removing the nodules that have been oxidized by oxygen ions using diluted HF solution.

According to another embodiment, a semiconductor device structure is provided. The semiconductor device structure includes a pair of epitaxial source/drain regions, a channel region between the epitaxial source/drain regions, and a gate structure on the channel regions. The gate structure comprises a gate spacer with one or more surface portions being oxidized and etched.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a plurality of stacks of semiconductor layers, each of the stacks including a plurality of first semiconductor layers and a plurality of second layers alternately stacked with each other;
forming a gate electrode structure on each of the stacks of semiconductor layers, each of the gate electrode structures including a gate spacer;
forming an epitaxial S/D feature in an opening between each pair of neighboring stacks of semiconductor layers;
applying oxygen ion beams on the gate spacers with a tilt angle to form oxidized materials on the gate spacers; and
removing the oxidized materials.

2. The method of claim 1, the oxidized materials comprising a plurality of nodules formed on the gate spacers while forming the epitaxial S/D features and oxidized by the oxygen ion beams.

3. The method of claim 2, further comprising removing the oxidized nodules with diluted HF solution.

4. The method of claim 3, wherein the diluted HF solution has a HF to water ratio of about 1:500.

5. The method of claim 2, wherein the nodules include n-type nodules and p-type nodules.

6. The method of claim 5, further comprising:
applying diluted HF solution to remove oxidized n-type nodules; and
applying water to remove oxidized p-type nodules.

7. The method of claim 2, wherein the oxidized materials comprise a plurality of portions of the gate spacers exposed between the nodules and oxidized by the oxygen ion beams.

8. The method of claim 7, wherein the exposed portions are oxidized with a depth of about 3 Å to about 50 Å.

9. The method of claim 7, further comprising removing the oxidized portions of the gate spacers by applying diluted HF solution.

10. The method of claim 8, wherein a surface of each of the gate spacers is roughened by removal of the oxidized portions thereof.

11. The method of claim 10, wherein the roughened surface has a roughness of about 3-4 Å to about 5-6 Å.

12. The method of claim 1, further comprising generating the oxygen ion beams from a CO source.

13. The method of claim 1, further comprising adjusting the tilt angle based on an aspect ratio of an opening between the gate structures.

14. A method for removing nodules formed on a gate spacer during formation of an epitaxial S/D feature in a semiconductor device structure, comprising:
applying directional oxygen ion beams to oxidize the nodules with a tilt angle adjusted to prevent oxygen ions applied to the epitaxial S/D features; and
removing the nodules that have been oxidized by oxygen ions using diluted HF solution.

15. The method of claim 14, further comprising oxidizing portions of the gate spacers by the oxygen ion beams.

16. The method of claim 15, further comprising forming a roughened surface of the gate spacers by removing the oxidized portions thereof.

17. The method of claim 14, wherein the diluted HF solution has an HF to water ratio no larger than about 1:500.

18. A semiconductor device structure, comprising:
a pair of epitaxial source/drain regions;
a channel region between the epitaxial source/drain regions;
a gate structure over the channel regions, the gate structure comprising a gate spacer with one or more surface portions being oxidized and etched.

19. The semiconductor device of claim 18, wherein the one or more portions have an oxidation depth of about 3 Å to about 50 Å.

20. The semiconductor device of claim 19, wherein the roughened surface of the gate spacer has a roughness of about 3-4 Å to about 5-6 Å.
